(19) United States
(12) Patent Application Publication
(10) Pub. No.: US 2025/0297967 A1
(43) Pub. Date: Sep. 25, 2025

(54) MULTISPOT OPTICAL SYSTEM AND METHODS OF USE

(71) Applicant: Verity Instruments, Inc., Carrollton, TX (US)

(72) Inventor: John Corless, Carrollton, TX (US)

(21) Appl. No.: 19/081,978

(22) Filed: Mar. 17, 2025

Related U.S. Application Data
(60) Provisional application No. 63/567,314, filed on Mar. 19, 2024.
(60) Provisional application No. 63/647,513, filed on May 14, 2024.

(51) Int. Cl. G01N 21/95; G01N 21/88; H01L 21/66

(52) U.S. Cl. CPC G01N 21/9501; G01N 21/8806; H01L 22/12; G01N 2021/8845; G01N 2201/0826

(57) ABSTRACT

The disclosure provides an optical system, a semiconductor processing system, and a method for processing a semiconductor wafer. In one example, the optical system includes: (1) a light source configured to provide source light to a source plane to form a plurality of first subbeams, (2) optical elements configured to modify each of the plurality of first subbeams to form a plurality of interrogation spots on a wafer according to a predetermined pattern, wherein the optical elements are further configured to modify each of the plurality of first subbeams upon reflection from the wafer to form a plurality of second subbeams upon an image plane, and (3) a spectrometer configured to receive collected light from the plurality of second subbeams.

### CROSS-REFERENCE TO RELATED APPLICATION

This application claims the benefit of U.S. Provisional Application Ser. No. 64/647,513, filed by John Corless on May 14, 2024, and U.S. Provisional Application Ser. No. 63/567,314, also filed by John Corless on Mar. 19, 2024, commonly assigned with this application and incorporated herein by reference in its entirety.

### TECHNICAL FIELD

This disclosure relates, generally, to optical spectroscopy systems and methods of use, and more specifically, to improvements to systems for multipoint monitoring of optical signals during semiconductor processes from within semiconductor processing equipment.

### BACKGROUND

Optical monitoring of semiconductor processes is a well-established method for controlling processes such as etch, deposition, chemical mechanical polishing and implantation. Optical emission spectroscopy (OES) and interferometric endpoint (IEP) are two basic types of modes of operation for data collection. In OES applications light emitted from the process, typically from plasmas, is collected and analyzed to identify and track changes in atomic and molecular species which are indicative of the state or progression of the process being monitored. In IEP applications, light is typically supplied from an external source, such as a flashlamp, and directed onto a workpiece. Upon reflection from the workpiece, the sourced light carries information, in the form of the reflectance of the workpiece, which is indicative of the state of the workpiece. Extraction and modeling of the reflectance of the workpiece permits understanding of film thickness and feature sizes/depth/widths among other properties.

### SUMMARY

In one aspect an optical system is disclosed. In one example, the optical system includes: (1) a light source configured to provide source light to a source plane to form a plurality of first subbeams, (2) optical elements configured to modify each of the plurality of first subbeams to form a plurality of interrogation spots on a wafer according to a predetermined pattern, wherein the optical elements are further configured to modify each of the plurality of first subbeams upon reflection from the wafer to form a plurality of second subbeams upon an image plane, and (3) a spectrometer configured to receive collected light from the plurality of second subbeams.

In another aspect the disclosure provides a semiconductor processing system. In one example, the processing system includes: (1) a processing chamber, (2) a light source configured to provide source light to a plurality of first optical fibers, (3) a spectrometer configured to receive collected light from a plurality of second optical fibers, and (4) an interrogation region including a plurality of interrogation spots on a wafer within the processing chamber, wherein each of the plurality of interrogation spots is defined by a pairwise arrangement of the pluralities of first and second optical fibers.

In still another aspect, a method for processing a semiconductor wafer is disclosed. In one example, the method includes: (1) illuminating a wafer within a semiconductor processing chamber via a plurality of first optical fibers with light provided by a light source, (2) collecting the light reflected from the wafer via a plurality of second optical fibers, (3) processing the collected light using a multiple input spectrometer, and (4) providing one or more control trends for controlling the processing of the wafer according to the processing.

### BRIEF DESCRIPTION OF THE DRAWINGS

Reference is now made to the following descriptions taken in conjunction with the accompanying drawings, in which:

FIG. 1 is a block diagram of a system for employing OES and/or IEP to monitor and/or control the state of a plasma or non-plasma process within a semiconductor process tool;

FIG. 2 is a simplified diagram of a beam forming portion of a typical refractive system used for IEP;

FIG. 3 is a simplified diagram of a multiplexed beam forming portion of a refractive system used for IEP, in accordance with this disclosure;

FIGS. 4A-4C are a set of plots of performance data representative of the design of a system of the type described in association with FIG. 3, in accordance with this disclosure;

FIGS. 5A-5D are 3D diagrams of an alternative multiplexed beam forming portion of a refractive system used for IEP, in accordance with this disclosure;

FIGS. 6A and 6B are further diagrams of the alternative multiplexed beam forming portion of a refractive system of FIGS. 5A-5D, in accordance with this disclosure;

FIG. 7 illustrates an example of a multi-mode optical circulator that can be used with a multi-point optical system as disclosed herein;

FIG. 8. illustrates an example of a target beam layout on a wafer;

FIG. 9 illustrates an example configuration of optical fibers for separating incoming and outgoing subbeams using fiber pairing and defocusing according to the principles of the disclosure;

FIGS. 10A and 10B illustrate examples of specific performance data and its variation with defocusing over different wavelength ranges for the fiber arrangement of FIG. 9;

FIG. 11 illustrates a block diagram of multiple optical, electrical, and computational components of a spectrometer and specific related systems in accordance with the principles of the disclosure;

FIG. 12 illustrates a computing device that can be used for processes disclosed herein, such as identifying signals in spectral data and processing the signals; and

FIG. 13 illustrates a flow diagram of a method 1300 for processing a semiconductor wafer according to the principles of the disclosure.

### DETAILED DESCRIPTION

In the following description, reference is made to the accompanying drawings that form a part hereof, and in which is shown by way of illustration, specific embodiments in which the invention may be practiced. These embodiments are described in sufficient detail to enable those skilled in the art to practice the invention, and it is to be understood that other embodiments may be utilized. It is also to be understood that structural, procedural and system changes may be made without departing from the spirit and scope of the present invention. The following description is, therefore, not to be taken in a limiting sense. For clarity of exposition, like features shown in the accompanying drawings are indicated with like reference numerals and similar features as shown in alternate embodiments in the drawings are indicated with similar reference numerals. Other features of the present invention will be apparent from the accompanying drawings and from the following detailed description. It is noted that, for purposes of illustrative clarity, certain elements in the drawings may not be drawn to scale.

The constant advance of semiconductor processes toward faster processes, smaller feature sizes, more complex structures, larger wafer, and more complex process chemistries places great demands on process monitoring technologies. For example, higher data rates are required to accurately monitor much faster etch rates on very thin layers where changes in Angstroms (a few atomic layers) are critical such as for fin field-effect transistor (FINFET) and three-dimensional NAND (3D NAND) structures. Wider optical bandwidth and greater signal-to-noise are required in many cases both for OES and IEP methodologies to aid in detecting small changes either/both for reflectances and optical emissions.

Large wafer sizes with smaller overall component feature sizes and stringent requirements for within-wafer and wafer-to-wafer uniformity poses many constraints upon semiconductor processing equipment design. These constraints may limit the introduction of features which support optical monitoring access. For example, typical interrogation of wafers has often used integration of signals over a single relatively large spot to characterize the representative state of a wafer process. With ever increasing complexity and diversity of structures, films, film stacks, and structure geometries on wafers, the use of a single large spot to characterize the representative state of the wafer is becoming deficient.

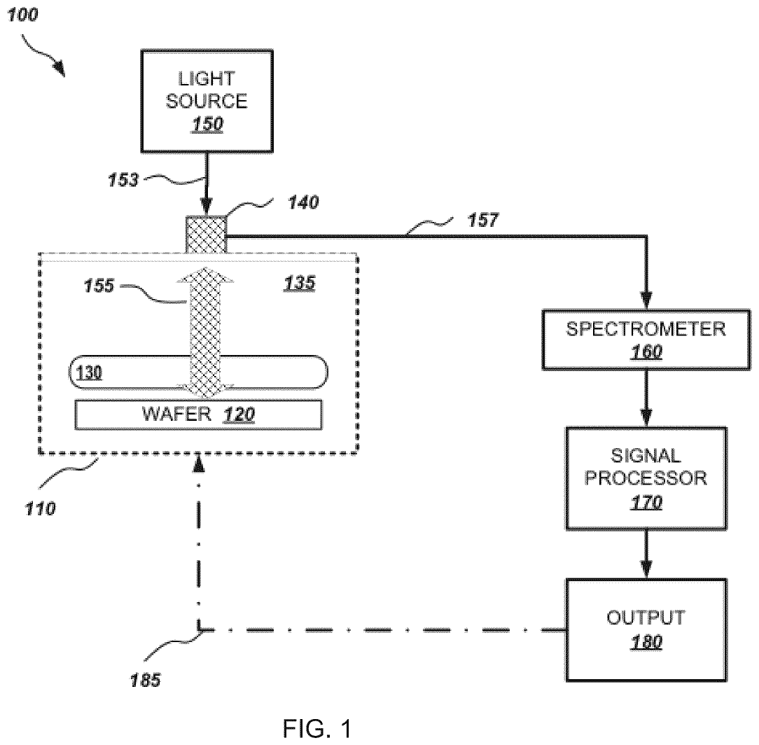

With specific regard to monitoring and evaluating the state of a semiconductor process within a process tool, FIG. 1 illustrates a block diagram of process system 100 utilizing OES and/or IEP to monitor and/or control the state of a plasma or non-plasma process within a semiconductor process tool 110. Semiconductor process tool 110, or simply process tool 110, generally encloses a workpiece, which is represented by wafer 120 in FIG. 1, and possibly process plasma 130 in a typically, partially evacuated volume of a processing chamber 135 that may include various process gases. Process tool 110 may include one or multiple optical interfaces 140 to permit observation into the processing chamber 135 at various locations and orientations. Interface 140 may include multiple types of optical elements such as, but not limited to, optical filters, lenses, windows, apertures, mirrors, beamsplitters, fiber optics, etc.

For IEP applications, light source 150 may be connected with interface 140 directly or via fiber optical cable assembly 153. As shown in this configuration, interface 140 is oriented normal to the surface of wafer 120 and often centered with respect to the same. Light from light source 150 may enter the internal volume of processing chamber 135 in the form of collimated beam 155. Beam 155 upon reflection from the wafer 120 may again be received by interface 140. In common applications, interface 140 may be an optical collimator. Following receipt by interface 140, the light may be transferred via fiber optic cable assembly 157 to spectrometer 160 for detection and conversion to digital signals. The light can include sourced and detected light and may include, for example, the wavelength range from deep ultraviolet (DUV) to near-infrared (NIR). Wavelengths of interest may be selected from any subrange of the wavelength range.

After detection and conversion of the received optical signals to analog electrical signals by the spectrometer 160, the analog electrical signals are typically amplified and digitized within a subsystem of spectrometer 160, and passed to signal processor 170. Signal processor 170 may be, for example, an industrial PC, PLC or other system, which employs one or more algorithms to produce output 180 such as, for example, an analog or digital control value representing the intensity of a specific wavelength or the ratio of two wavelength bands. Instead of a separate device, signal processor 170 may alternatively be integrated with spectrometer 160. The signal processor 170 may employ an OES algorithm that analyzes emission intensity signals at predetermined wavelength(s) and determines trend parameters that relate to the state of the process and can be used to access that state, for instance end point detection, etch depth, etc. For IEP applications, the signal processor 170 may employ an algorithm that analyzes wide-bandwidth portions of spectra to determine a film thickness. For example, see System and Method for In-situ Monitor and Control of Film Thickness and Trench Depth, U.S. Pat. No. 7,049,156, incorporated herein by reference. Output 180 may be transferred to process tool 110 via communication link 185 for monitoring and/or modifying the production process occurring within chamber 135 of the process tool 110.

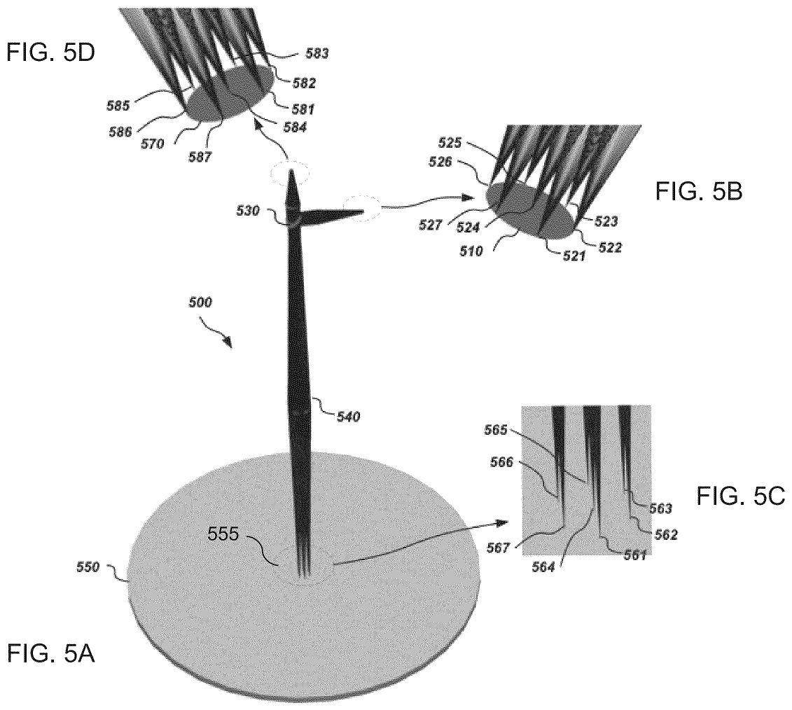

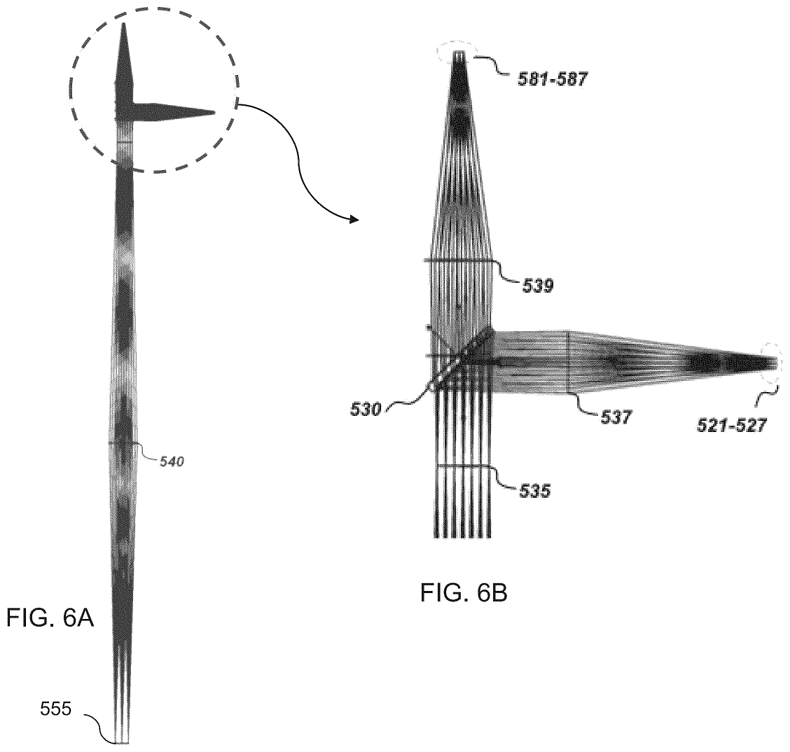

The shown and described components of FIG. 1 are simplified for expedience and are commonly known. In addition to common functions, the spectrometer 160 or the signal processor 170 can also be configured to identify stationary and transient optical and non-optical signals and process these signals according to the methods and/or features disclosed herein. As such, the spectrometer 160 or the signal processor 170 can include algorithms, processing capability, and/or logic to identify and process optical signals and temporal trends extracted therefrom. Additionally, the spectrometer 160 or the signal processor 170 can also be configured to process multi-signal points that are collected (multi-collected signal points) according to the apparatuses, systems, and methods disclosed herein. For example, FIGS. 5A-5D, and 6A-6B provide examples of collecting specific spatial information from multi-collected signal points or reflected subbeams. Using FIGS. 5A to 5D as an example, the reflected subbeams 581-587 (also referred to as multi-collected signal points) can be provided to spectrometer 160 via fiber optic cable assembly 157, which in this example would have seven individual fibers (one for each of the subbeams). The optical signals from each of the individual subbeams 581-587 can be provided to a unique input of the spectrometer 160 and can be processed in multiple ways. For example, each of the subbeams 581-587 can be processed individually (or independently), in combination with at least one more of the subbeams 581-587, or all of the subbeams 581-587 can be processed together.

The number of subbeams collected can correspond to the number of individual optical inputs of the spectrometer 160. However, the number of subbeams is not limited by the number of optical inputs. For example, the collected subbeams can be multiplexed and provided to the optical inputs. As such, the number of subbeams collected can be greater than the number of optical inputs for the spectrometer 160 (i.e., the number of collected subbeams can be greater than the number of inputs N). The number of collected subbeams can also be fewer than the number of optical inputs N (i.e., the number of collected subbeams can be less than the number of inputs N). The collected subbeams can be from IEP or OES operating modes. The number of collected subbeams can be, for example, between two to ten subbeams.

Additional processing can also be performed on the processed subbeams. For example, the signal processor 170 may perform additional processing based on the combined information from individually processed subbeams, such as averaging output values from the processed subbeams 581-587. Various trends or different types of data could be extracted from processing the output values of the processed subbeams 581-587. The information obtained can be provided to the process tool 110 to, for example, control a process. Trend lines can also be determined and control signals generated based upon the processing of one or more of the subbeams. For example, seven independent trend lines can be determined and sent as seven parallel control signals based on the seven subbeams 581-587.

The algorithms, processing capability, and/or logic can be in the form of hardware, software, firmware, or any combination thereof. The algorithms, processing capability, and/or logic can be within one computing device or can also be distributed over multiple devices, such as the spectrometer 160 and the signal processor 170. Although this system and others described herein are based upon refractive systems, it should be understood that systems based upon reflective and/or combined refractive/reflective systems are possible and may be created and adapted from the principles and examples described and disclosed herein.

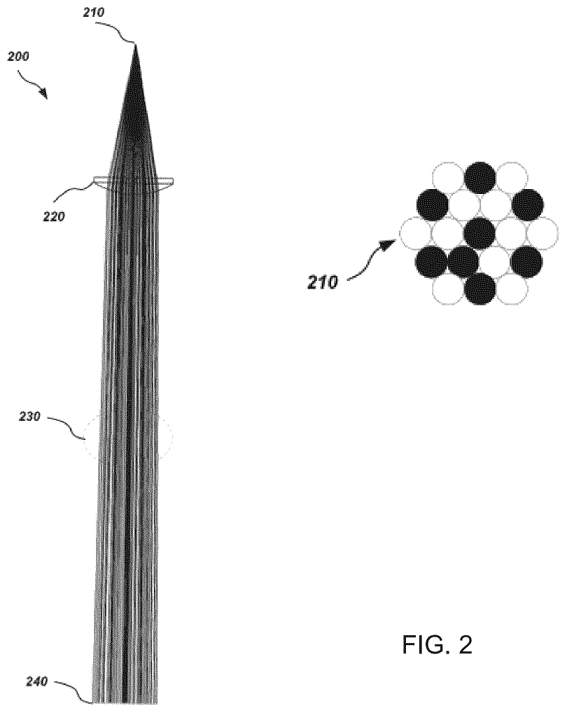

FIG. 2 shows a simplified diagram of a beam forming subsystem 200 of a typical refractive system used for IEP. Subsystem 200 generally includes source and receive fiber optical cable subassembly 210 (example of fiber optical cable assembly 153), which may be formed from two or more individual optical fibers arranged to provide light to subsequent components and to receive light from previous components of beam forming system 200. Enlarged inset of fiber optical cable subassembly 210 shows, for example, a random arrangement of 19 optical fibers arranged in a close-packed or hex-packed configuration. In this example 8 of the optical fibers (colored black) may be considered as source optical fibers and 11 of the optical fibers (colored white) may be considered as receive optical fibers. The source optical fibers direct light toward lens 220 which refracts the light and so forms beam 230 (which can correspond to 155 of FIG. 1) that is directed toward the wafer 240. Upon reflection from the wafer 240, light passes through lens 220 and is collected by the receive optical fibers.

Lens 220 (which can form the basis of interface 140) may typically have a diameter ranging from 0.5″ to 1.0″ and has a focal length appropriate to the numerical aperture (NA) and other properties of the system. In place of a singlet lens as shown, lens 220 may be substituted by using a doublet, triplet or other complex lens group or may be substituted by equivalent reflective elements. For collimated systems, the spot size of the beam produced by lens 220 on wafer 240 is typically similar in diameter to the clear aperture of lens 220. For focused systems, the spot size of the beam on wafer 240 may be similar to the diameter of the fiber bundle of the fiber optical cable subassembly 210, such as represented by the enlarged inset, or modified by the designed magnification of the optical system.

Generally, subsystem 200 provides a measurement over the spot size that is an average of the optical response over the entire region. This large region may include diverse structures and/or film stacks that individually provide very different signals that when incoherently summed in this subsystem are obscured and not available for characterization and process control. Division of this integrated signal into sub portions is possible via aperturing of the beam and/or by individually collecting and processing signals from each of the individual receive optical fibers. However, these methods do not generally provide specific spatial information from wafer 240 as the combined action of the optical fibers of the fiber optical cable subassembly 210 and the lens 220 mixes signals over both space and angle.

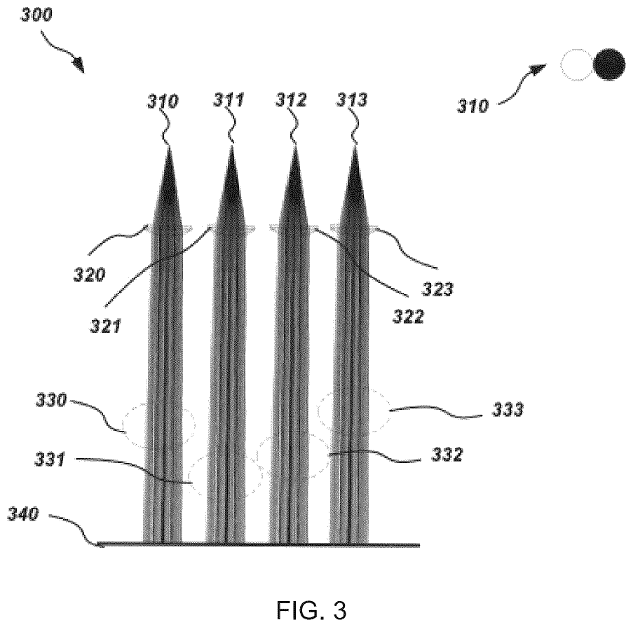

As shown in FIG. 3 specific spatial information may be provided via multiplexing and possibly miniaturizing subsystem 200 of FIG. 2. Subsystem 300 includes a multiple of discrete sets of lenses and fiber optical cables to provide the multiple individual sets of spatial information. Fiber optical cable subassemblies 310-313 may each be composed of a limited number of fibers such as a single pair of a source and receive fiber as shown enlarged for subassembly 310. The fibers may be of various commonly available core diameters such as 50, 100, 200, 400, and 600 microns. A limited number of fibers assists in miniaturization. The lenses 320-323 of subsystem 300 (which can correspond to interface 140 of FIG. 1) may be physically discrete and form what may be called a “beamlet” system (as shown) or may be physically conjoined and form what may be called a “lenslet” system. Lenses 320-323 may be singlet lenses or more complex lens groups. Each fiber optical cable and lens pair (e.g., 310 and 320) cooperate to form a beam (e.g., 330). Other pairs form beams 331-333. All beams may reflect from and provide information from spatial distinct regions of wafer 340. Beams 330 to 333 can correspond to beam 155 of FIG. 1. The source and receive fibers can be radially symmetric with respect to an axis of the optical system. For example, the pair of source and receive fibers of subassembly 310 can be pairwise radially symmetric with the axis of lens 320.

Although subsystem 300 shows 4 combinations of fiber, lens and beam in a 1D linear pattern, any number of combinations may also be placed into 2D patterns such as square arrays, hexagonal arrays, circular patterns, etc. Sizes of individual beam spots on wafer 340 and the bounding region for a collection of lenslet or beamlet combinations may be designed to suit specific or general applications. For example, individual beam spots may be in a range of diameters from less than 1 mm to more than 5 mm and the complete subsystem may be bounded in a region of 25 mm diameter upon wafer 340. Selection of individual beam size and bounding region may be determined based upon feature sizes, pattern densities, and other properties of wafer 340. Alternatively, or additionally, selection of individual beam size and bounding region may be determined based upon process parameters such as non-uniformity requirements or tool requirements such as available physical access.

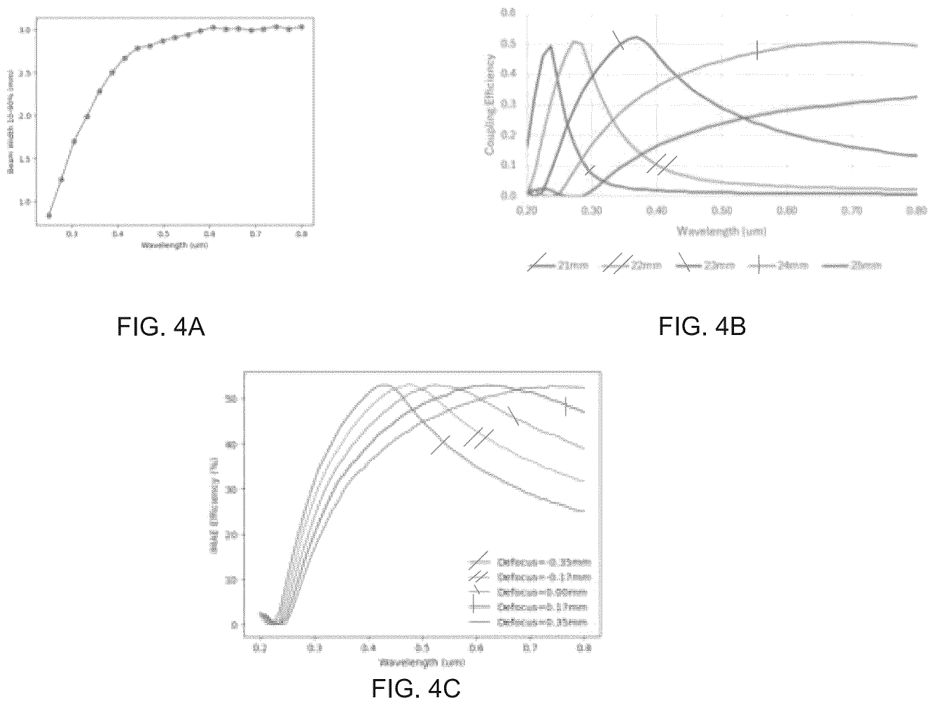

Design and optimization of each combination is subject to design parameters such as fiber core size and number of fibers for source and receive, the focal length of the lens, the NA of the overall combination, requirements for spot size uniformity over wavelength, etc. Especially for systems based upon singlet lens designs, focal length and wavelength sensitivities can lead to significant coupling efficiency and spot size variations. Furthermore, miniaturization of these systems and tolerance variations of lens, fibers, and mechanical components add challenges to alignment of fibers to lens and lens to each other into mechanical fixtures for actual implementation of the systems into processing tools. FIGS. 4A-4C are a set of plots of performance data representative of the design of a system of the type described in association with FIG. 3.

FIG. 4A is a plot of beam spot size versus wavelength showing the strong variation of diameter in the UV region with wavelengths less than approximately 0.4 microns. FIG. 4B is a plot of signal coupling efficiency versus wavelength showing the wavelength dependence as the system varies the spot size and the degree of focus or collimation of the light at the wafer surface depending on the nominal fiber-to-lens distance for a given focal length lens. FIG. 4C is a plot of signal coupling efficiency versus wavelength over a variation in the defocus distance of the fiber to the lens, which highlights the system sensitivity to at least one mechanical tolerance. The efficiency is represented as IMAE efficiency that corresponds to the IMAE operand used to perform analysis by the optical design software ZEMAX.

FIGS. 5A-5D are 3D diagrams of an alternative multiplexed beam forming portion of a refractive system 500 used for IEP. A single interface, such as interface 140, is represented but more beams can be used with wafer 550 with more optical interfaces. FIG. 5A shows source plane 510 providing light to form subbeams 521-527 (e.g., multi-source signal points or simply multi-source points), which are directed toward beamsplitter 530 that subsequently directs the light to lens 540 and thereafter onto wafer 550 forming interrogation spots 561-567 (e.g., multi-interrogation signal points or simply multi-interrogation points). Upon reflection from wafer 550, the subbeams pass again through lens 540 and subsequently through beamsplitter 530 to reach image plane 570 where each reflected subbeam 581-587 (e.g., multi-collected signal points or simply multi-collected points) may be independently collected by corresponding optical fibers (not shown). The correspondence between the different signal points (e.g., the multiple source, interrogation, and collected points) can be one to one. The number of subbeams can be, for example, between two to ten.

The working f # and magnification of system 500 may be determined based upon required working distances and magnification. For example, a system based upon lens 540 with a nominal focal length of 5F and other lenses in the system with nominal focal length of F (such as lenses 537 and 539 of FIG. 6B) provides a 5× magnification. In the example described, lens 540 may have a focal length of 200 mm and a diameter of 20 mm. This lens choice results in a system where the working distance (distance from lens 540 to wafer 550) is approximately 200 mm. When 200 um core optical fibers are used with this system, the source and signal subbeams will each be nominally 200 um diameter and the interrogation spot size will nominally be 1000 um diameter.

FIG. 5B shows an enlarged region about source plane 510 and subbeams 521-527. In this example, seven subbeams are represented but more or less may be defined and used. Source plane 510 may be a common source plane such as from a light pipe that has a diameter sufficiently large to enclose the source points for all desired subbeams. For example, for interrogation spot sizes of ˜1 mm diameter and a system operating at a magnification of 5X, a light pipe may be approximately 3 mm or larger in diameter to enable an interrogation region (including all individual interrogation spots) of approximately 15 mm. The light pipe may commonly be formed of fused silica for wide spectrum (200-800 nm) performance or may be of other suitable materials. Illumination of the light pipe may be provided by a light source such as a pulsed Xenon flashlamp.

The use of a light pipe to define the source plane and a common source of the subbeams may provide benefits over the use of individual optical fibers for each subbeam. For example, the light pipe provides a common uniform source plane whereas individual fibers may have to be independently focused. Additionally, the light pipe provides a large areal source field that does not require individual lateral alignment of individual source fibers to individual signal fibers. Furthermore, the use of a light pipe providing uniform illumination may allow for the removal of the individual source fibers when the uniform illumination from the light pipe illuminates a larger interrogation region and the individual receive fibers may receive any subset of light reflected within that region. Therefore the system may be considered self-aligning and requires less complex alignment and construction of the signal receiving optical fiber assembly. Self-aligning may include the allowable freedom of alignment of the individual source fibers to the light pipe or light source and/or the allowable freedom of the alignment of the signal fibers with respect to the larger illuminated interrogation region provided by the light pipe. For example, the source light pipe can create a uniform plane of illumination that when it passes through the optical system samples the wafer continuously across the region of its image on the wafer. Then the reflected light passes back through the optical system and is re-imaged onto plane 570. Individual fibers are placed in the receive plane to receive the returned light. Each receive fiber collects a subset of the whole beam that originated from a specific location on the light pipe, travelled to the wafer and probed a specific location on the wafer, and then reflected back into the fiber. This is self-aligning in the sense that the receive fiber could be moved and it would still collect valid light from the wafer but just in a translated position on the wafer and having originated from a slightly different position on the light pipe. Compared to individual optical fiber sources, a light pipe may also offer improved uniformity of illumination intensity for each subbeam.

FIG. 5C shows an enlarged interrogation region 555 about the intersection of the incident subbeams 561-567 with wafer 550. As mentioned above subbeams may provide interrogation spot diameters of approximately 1 mm to 5 mm and be enclosed within an overall diameter of approximately 15 mm to 50 mm. FIG. 5D shows an enlarged region about signal plane 570 and signal subbeams 581-587. Each signal subbeam may be approximately 1 mm apart and arranged in a hexagonal pattern. The pattern may be defined in accord with the construction of a mating optical fiber cable assembly (not shown). The pattern can also be subject to features to be examined on the wafer 550. Engineering preferences, wafer design, OEM requirements, are examples of some other bases for pattern selection.

In cooperation with the source light pipe, a mating optical fiber assembly may be changed or reconfigured without the need to alter the source of the subbeams to provide a new pattern of wafer sampling. As such, the light source can stay the same while the configuration of collected subbeams is adaptable. This pattern change may include a different spatial mapping, different interrogation spot sizes (via optical fiber core size change), different number of collected subbeams, etc. Additionally, the source and signal functions of the system may be reversed by illuminating the system via the signal fibers and collecting light at the source plane. This functionality may be used to add an adjustability mechanism to fiber layout to allow fine-tuning of measurement locations (e.g., run light in reverse to give probe beams to illuminate wafer 500 for setup purposes).

FIGS. 6A-6B are further diagrams of the alternative multiplexed beam forming portion of a refractive system 500 of FIGS. 5A-5D. FIG. 6A shows a cross-sectional view of system 500 to permit indication of beam stop 535 and further details as shown in FIG. 6B. Beam stop 535 resides at the focal plane of system 500 and controls the bi-telecentric performance of system 500. Bi-telecentric system performance is valuable in system 500 so that all subbeams of each type of subbeam: source subbeams 521-527, interrogation subbeams 561-567, and signal subbeams 581-587 are formed on a common surface and normally incident on interrogation and signal surfaces. This avoids individual longitudinal adjustments for each subbeam on one or more of the source plane, wafer surface, or signal plane.

FIG. 6B shows an enlarged portion of FIG. 6A to show various additional features of system 500. Subbeams 521-527 upon leaving the source plane pass through and may be collimated by lens 537. Lens 537 may be a singlet lens, doublet, or other more complex lens group. Subsequent to lens 537, the subbeams approach and are reflected by beamsplitter 530. Beamsplitter 530 may be, for example, a broad-spectrum polka-dot beamsplitter, a cube beamsplitter or other known beamsplitter types with or without coatings. For the design as described, beamsplitter 530 may be approximately 25 mm in diameter. After reflection from beam splitter 530 subbeams are directed through beam stop 535 which for example may be from 10 mm to 20 mm in diameter and may depend upon the system magnification, working distances, and interrogation beam spot sizes. Beam stop 535 is placed a focal length away from lens 537 so the system is telecentric in object space. Lens 540 (FIG. 6A) is placed its focal length from beam stop 535 so that the subbeams are telecentric at the wafer plane and therefore incident normally to the wafer plane. Subsequent to reflection from the wafer 550 (more specifically the interrogation region 555 of wafer 550) and passing through beam splitter 530, subbeams enter and may be focused by lens 539. Lens 539 may be equivalent to lens 537 in material composition and properties, for example being a fused silica singlet or air-spaced doublet with a 40 mm focal length and ˜12 mm diameter. Lens 539 is placed its focal length away from beam stop 535 so that the beams are telecentric in the signal plane to aid in efficient coupling to signal fibers. Note that two lenses 537 and 539 are shown but depending on focal length and NA requirements it is possible that a single lens could be used with the beam splitter 530 being placed in the converging region of this single lens group to provide the splitting of outgoing and incoming subbeams. Lens 540 and the components of FIG. 6B can correspond to interface 140 of FIG. 1.

The bi-telecentric system described and shown in association with FIGS. 5A-5D and FIGS. 6A-6B may be modified into a simpler system with the removal of specific elements and adjustments to other elements. These changes to the bi-telecentric result in certain performance trade-offs and limitations but may also provide certain advantages in reduced system complexity, cost and size. Specifically, the simplified system based upon system 500 can remove lenses 537 and 539 and can also remove or reposition stop 535. The focal length and position of lens 540 with respect to the beam splitter 530 and wafer 550 can also be adjusted. The location of lens 540 may define the system stop. Generally, beamsplitter 530 is retained for separation of source and signal subbeams due to the double-conjugate nature of the imaging in this double-pass optical system. As in system 500, a light pipe may be used for the source in this simplified system to ease alignment to signal fibers and enable easier configurability with potential signal fiber changes supporting interrogation spot size and/or location. With the simplified system, multi-source points do not have to be used to collect multi-signal points. Advantageously, this eliminates, or at least reduces, aligning of at least the multi-points for sourcing with the multi-points for collecting. Thus, a single larger light beam may be created on the wafer 550 with the simplified system compared to system 500 but the same effective probe pattern can be used on the wafer 550 as in system 500 when the same configuration of collected subbeams is used. Additionally, as with system 500 the light source of the simplified system may be considered self-aligning and the light source can stay the same while the configuration of collected subbeams is changed. Thus, the simplified system can also have an adaptable pattern of interrogation spots.

As compared to the bi-telecentric system design, the simplified system provides a narrower and limited field-of-view which can result in interrogation subbeams, such as subbeams 561-567 of FIG. 5C not all intersecting the wafer surface normally. Specifically, a central on-axis subbeam, such as subbeam 564, may intersect wafer 550 normally but peripheral subbeams, such as 561-563 and 565-567, may not intersect the wafer normally. The narrower field-of-view may also manifest as subbeam-to-subbeam intensity variation with the highest intensity subbeam being on-axis and lower intensity subbeam at the periphery. Variations in field-of-view and intensity limitations may be adjusted to accommodate required system performance by design changes to, at least, lens radii, working distances, source/signal/interrogation spot sizes, optical fiber diameters, and overall interrogation spot diameters.

One aspect to consider in a multi-point system is separating source subbeams from signal subbeams given that an imaging design naturally returns light to the same location. For example, in system 500, source plane 510 and signal plane 570 are conjugate and would overlap if not spatially separated using beamsplitter 530. One option for a multi-point optical system that helps with the beam separation challenge is using a multi-mode optical circulator.

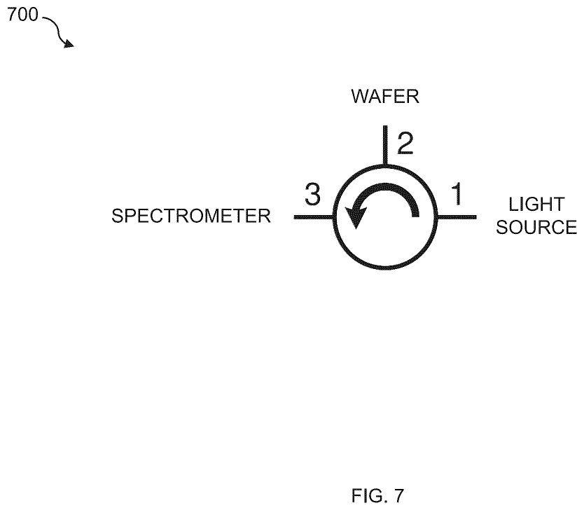

FIG. 7 illustrates an example of a multi-mode optical circulator 700 that can be used with a multi-point optical system as disclosed herein, such as system 500. For example, multiple of the multi-mode optical circulators 700 can be used in place of the beamsplitter 530 and may simplify system integration and alignment of other elements such as beam stop 535, lens 537, and lens 539. Using circulator 700, in certain system configurations, elements such as lenses 537 and 539 may be removed from the system and not used. The multi-mode optical circulator 700 is a three-port device that is configured such that light travels in only one direction and light entering any port exits from the next port. As such, light entering port 1 from a light source can be provided to a wafer via port 2 and light entering port 2 from the wafer can be provided to a spectrometer via port 3. Using FIG. 5 as an example, subbeam 524 entering at port 1 is provided as subbeam 564 to wafer 550 as an interrogation point via port 2 and subsequently via port 2 reflected subbeam 564 is provided to the spectrometer via port 3. Specifically, through the function of circulator 700, direct optical signal communication between port 1 (light source) and port 3 (light signal) is avoided as any light signal provided in this manner would not include the desired information from the wafer and therefore be considered erroneous or background signal. The individual ports of circulator 700 may be formed from multiple individual multi-mode optical fibers and a single optical fiber can be connected to each port. Accordingly, the multi-mode optical circulator 700 can enable using a single optical fiber on port 2 for both an interrogation subbeam and a collection subbeam. As with subbeams 524, 564, and 584, a multi-mode optical circulator 700 can be used for each of the corresponding multi-point subbeam sets of system 500. For example, regarding FIG. 5A-5D, seven circulators 700 may be used to replace beamsplitter 530 and lenses 537 and 539. The optical fibers for each port 1 can be separately or via use of a unified optical connection be coupled to the light source, such as via source plane 510. The optical fibers of port 2 can be incorporated into a single optical termination such as an SMA termination and spatially configured in a desired pattern to provide the multiple interrogation spots of the interrogation region 555. Each of the optical fibers of port 3 can be provided to a unique channel of a multi-channel spectrometer, such as spectrometer 160 via fiber optic cable assembly 157. Additionally, source fibers and receive fibers, such as for subbeams 524 and 584, can be configured in pairs using optical circulators such as the multi-mode optical circulator 700. The multi-mode optical circulator 700 can be used with, for example, 400 to 800 nm systems or with wider bandwidth systems such as 200-800 nm. To increase robustness, BX jacketing can be used with the optical fibers connected to multi-mode optical circulator 700. An optical subsystem using a circulator may include appropriately placed aperture stops to make the optical system act telecentrically for improved uniformity of source and signal levels over the multiple interrogation spots within an interrogation region.

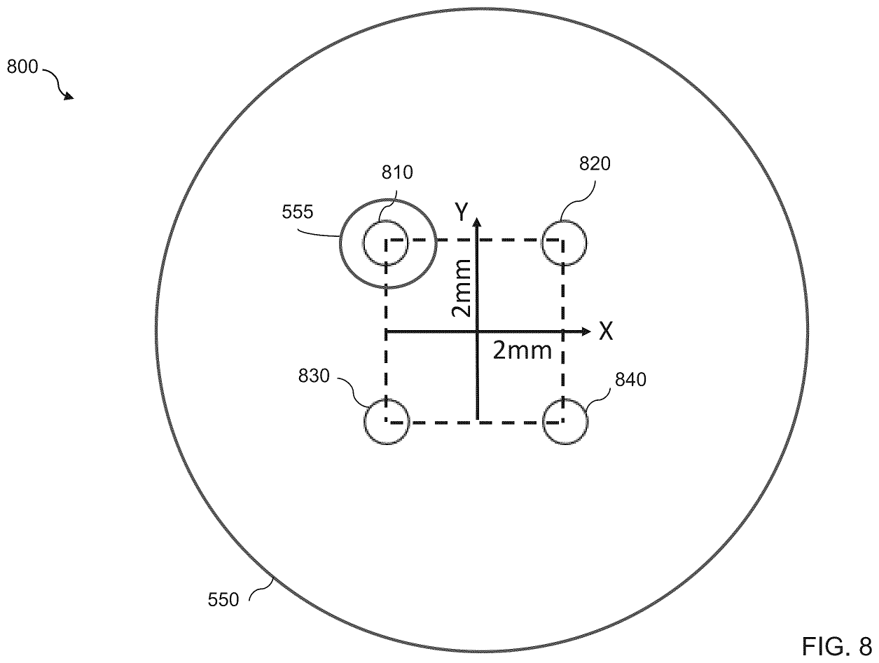

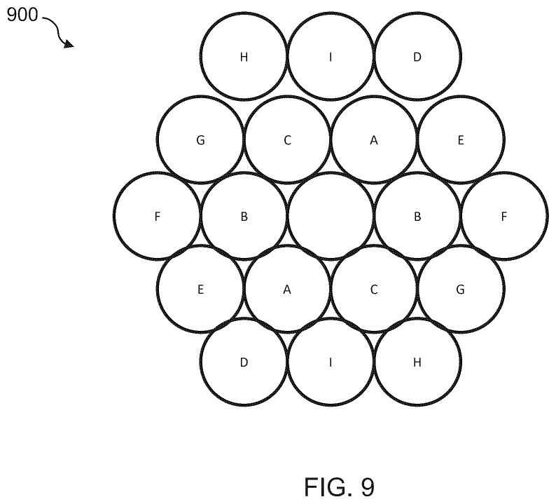

FIG. 8 illustrates an example of a target beam layout 800 on a wafer, such as wafer 550, which is used as an example. The example target beam layout 800 includes four subbeams 810, 820, 830, 840, that are provided to the wafer 550. Each of the subbeams 810, 820, 830, 840, can correspond to a single beam 155 and optical interface 140 as shown in FIG. 1. In other words, target beam layout 800 can represent the layout of four optical interfaces 140 and beams 155. Each of the individual beams on wafer 550 are shown as 1 mm circles that are +/−2 mm from the origin in X and Y directions. Rectangular beam layout 800 is an example of a beam layout that may be used in place of the hexagonal beam layout represented in FIGS. 5A-5D. As an example, subbeam 810 is shown within interrogation region 555 of wafer 550 and will be used in following discussion of FIG. 9 to illustrate a further fiber and optical configuration that combines features of one or more precedingly discussed configurations.

FIG. 9 illustrates an example pairwise fiber configuration 900 for separating incoming and outgoing subbeams using defined fiber patterning (spatial mapping) and defocusing according to the principles of the disclosure. Similar as shown in FIG. 3, optical fibers may be used in pairs but also similar to FIG. 2, the pairs of optical fibers may be integrated into a common bundle of multiple pairs of optical fibers. The fiber configuration 900 may be used with a single lens such as lens 220 of FIG. 2 and avoid the optomechanical complexity of multiple lenses such as 320-323 of FIG. 3 or beamsplitter 530 of FIG. 5. As noted in the discussion of FIG. 2, the use of a single lens and a randomized fiber pattern results in a lack of specific spatial information, however, with a pairwise fiber pattern and the use of defocusing of the optical system, specific spatial information may be at least partially received. In the fiber layout 900, each fiber pair is labeled with a common letter, i.e., A/A is a first pair, B/B is a second pair etc. Due to symmetry, it is not required that the specific receive fiber or source fiber be identified and are generally interchangeable but should be coordinated with the appropriate selection of light source of light or spectrometer as required. Each receive and source fiber pair is displaced radially from the axis of symmetry of the optical system which may be defined by the use of a lens such as lens 220 of FIG. 2. Receive and source fiber pair A/A may correspond to subbeam 810 of FIG. 8 and additional fiber pairs (e.g., B/B, C/C and D/D) correspond to subbeams 820, 830, and 840. The fiber configuration 900 may be integrated into single or multiple lens subsystem designs including the subsystems 200 and 300.

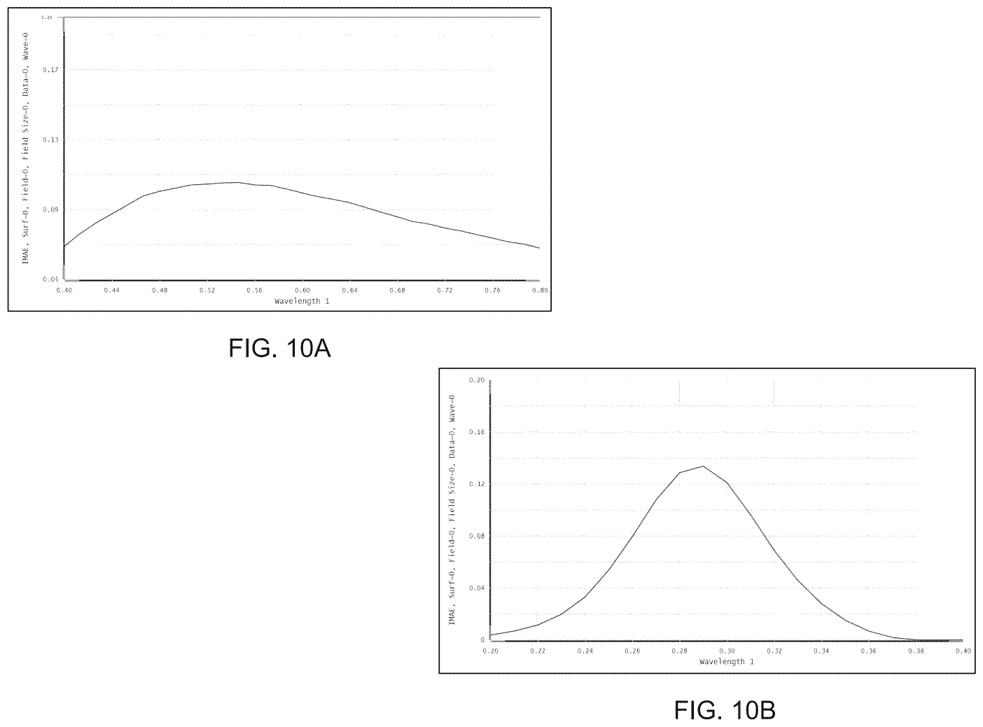

Although fiber configuration 900 indicates specific fiber pairing and a specific arrangement and number of the pairs, it should be understood that more or less pairs may be used and that multiple other pairwise combinations may be defined and used. Additionally, as with the unlabeled central fiber, a certain individual fiber may be unused within a fiber pair and simply provide the required geometry. Furthermore, although fiber pairing has been used herein as an example it should be understood that more complex groupings are possible. For example pairs of triplets A/D/I may be combined and used to define larger interrogation spots. FIGS. 10A and 10B illustrate, for a pairwise design used with a singlet lens, examples of how defocusing, as an optimization parameter for the subsystem, influences signal efficiency (IMAE parameter of Zemax modeling software). FIG. 10A shows defocusing of 0.22 mm for a range of 400 to 800 nm wavelengths with a resulting average value of approximately 0.08. FIG. 10B shows defocusing of −3.4 mm for a range of 240 to 340 nm wavelengths with increased efficiency over a narrow range and corresponding lower efficiencies over other wavelengths.

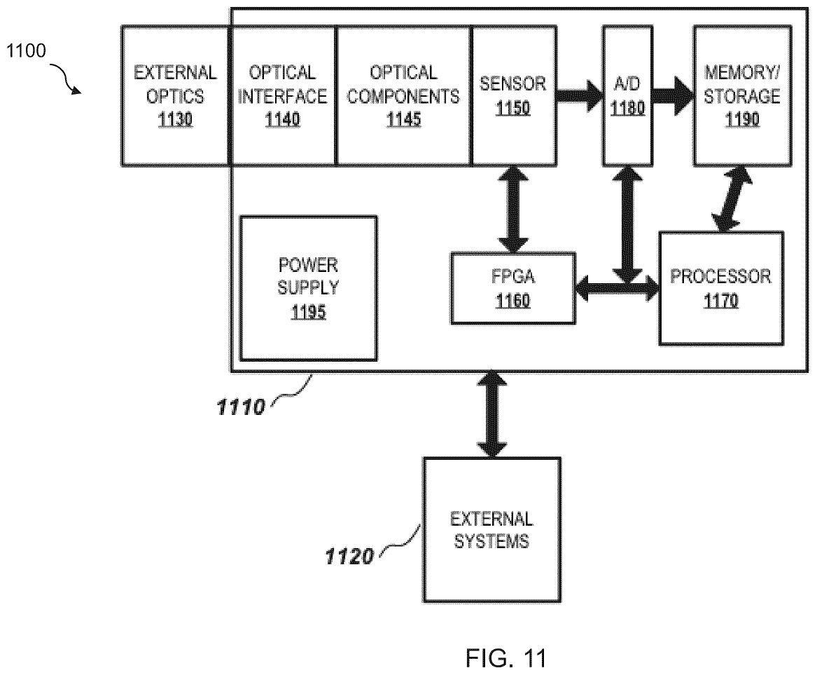

FIG. 11 is a block diagram of an optical system 1100 including a spectrometer 1110 and specific related systems, in accordance with one embodiment of this disclosure. Spectrometer 1110 may incorporate the system, features, and methods disclosed herein to the advantage of measurement, characterization, analysis, and processing of optical signals from semiconductor processes and may be associated with spectrometer 160 of FIG. 1. Spectrometer 1110 may receive optical signals from external optics 1130, such as via fiber optic cable assemblies 157 or 159, and may, following integration and conversion, send data to external systems 1120, such as output 180 of FIG. 1, which may also be used to control spectrometer 1110 by, for example, selecting a mode of operation or controlling integration timing as defined herein. Spectrometer 1110 may include optical interface 1140 such as a subminiature assembly (SMA) or ferrule connector (FC) fiber optic connector or other opto-mechanical interface. Further optical components 1145 such as slits, lenses, filters and gratings may act to form, guide and chromatically separate the received optical signals and direct them to sensor 1150 for integration and conversion. Low-level functions of sensor 1150 may be controlled by elements such as FPGA 1160 and processor 1170. Following optical to electrical conversion, analog signals may be directed to A/D convertor 1180 and converted from electrical analog signals to electrical digital signals which may then be stored in memory 1190 for immediate or later use and transmission, such as to external systems 1120 (c.f., signal processor 170 of FIG. 1). Although certain interfaces and relationships are indicated by arrows, not all interactions and control relations are indicated in FIG. 11. For example, multiple subbeams can be collected as disclosed herein for processing with appropriate adaptation of, for example, optical interface 1140 to include multiple individual input capability for each signal subbeam. As such, spectrometer 1100 can be configured (i.e., designed, constructed, or programmed, with the necessary logic and/or features for performing a task or tasks) for processing multiple subbeams. Spectrometer 1110 also includes a power supply 1195, which can be a conventional AC or DC power supply typically included with spectrometers.

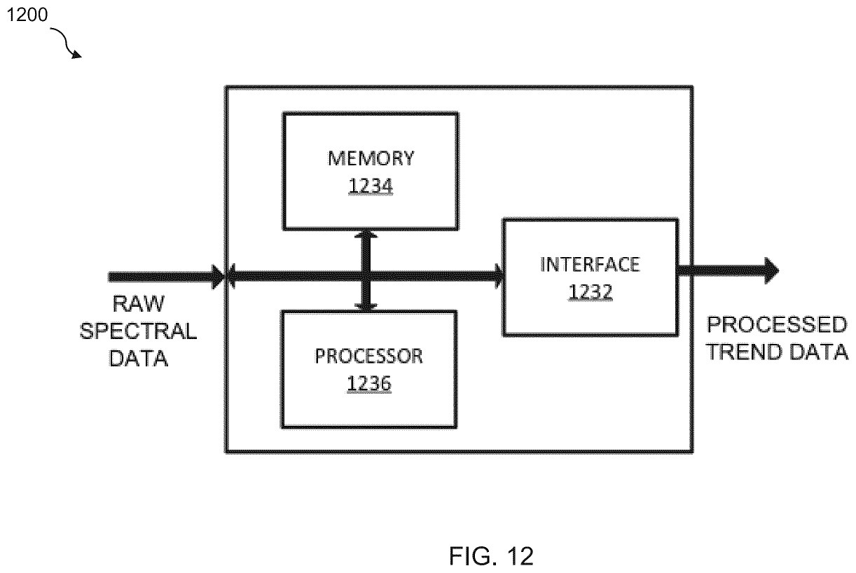

FIG. 12 illustrates a computing device 1200 that can be used for processes disclosed herein, such as identifying signals in spectral data and processing the signals. The computing device 1200 can be a spectrometer or a portion of a spectrometer, such as spectrometer 160 or 1110 disclosed herein. The computing device 1200 may include at least one interface 1232, a memory 1234 and a processor 1236. The interface 1232 includes the necessary hardware, software, or combination thereof to receive, for example, raw spectral data and to transmit, for example, processed spectral data. A portion of the interface 1232 can also include the necessary hardware, software, or combination thereof for communicating analog or digital electrical signals. The interface 1232 can be a conventional interface that communicates via various communication systems, connections, busses, etc., according to protocols, such as standard protocols or proprietary protocols (e.g., interface 1232 may support I2C, USB, RS232, SPI, or MODBUS). The memory 1234 is configured to store the various software and digital data aspects related to the computing device 1200. Additionally, the memory 1234 is configured to store a series of operating instructions corresponding to an algorithm or algorithms that direct the operation of the processor 1236 when initiated to, for example, process multiple subbeams collected as disclosed herein. The memory 1234 can be a non-transitory computer readable medium (e.g., flash memory and/or other media).

The processor 1236 is configured to direct the operation of the computing device 1200. As such, the processor 1236 includes the necessary logic to communicate with the interface 1232 and the memory 1234 and perform the functions described herein to identify and process multiple collected subbeams.

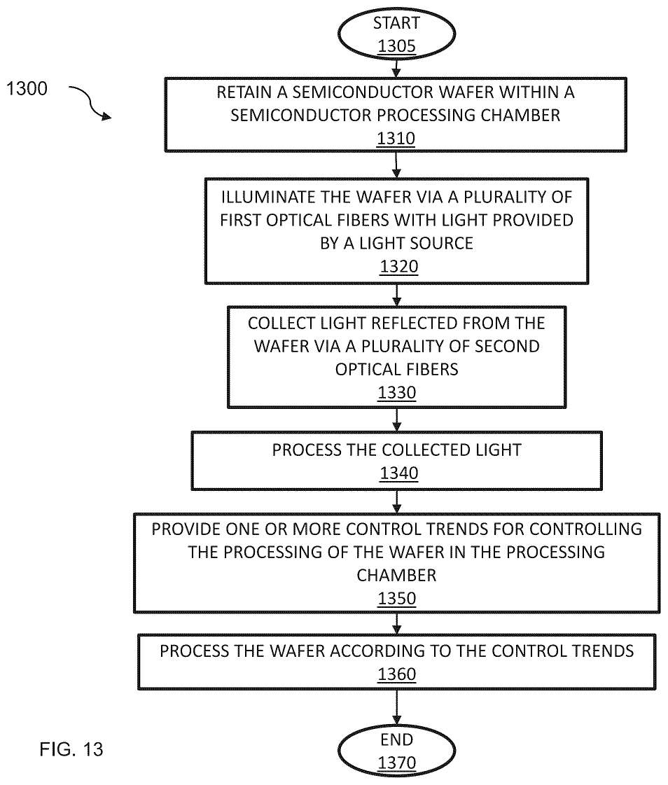

FIG. 13 illustrates a flow diagram of a method 1300 for processing a semiconductor wafer according to the principles of the disclosure. The method 1300 can be carried out using, for example, one or more of the optical systems disclosed herein, such as in FIG. 1. The method 1300 begins in step 1305.

In step 1310, a semiconductor wafer is retained within a semiconductor processing chamber. The semiconductor processing chamber can be a typical chamber used for processing semiconductor wafers and the wafer can be retained according to industry practices.

The wafer is illuminated in step 1320 via a plurality of first optical fibers with light provided by a light source. The first optical fibers can be source optical fibers such as disclosed herein. The light source can be, for example, a Xenon flash lamp. A light pipe can be used with the light source.

The wafer can be illuminated at various interrogation spots. The interrogation spots on the wafer can be according to a predetermined pattern. The pattern can be, for example, a linear pattern, a circular pattern, a hexagonal pattern, or a rectangular pattern. Other two dimensional patterns can also be used. The pattern may be defined in accordance with the construction of a mating optical fiber cable assembly and can also be subject to, for example, features to be examined or monitored on the wafer, engineering preferences, wafer design, or OEM requirements. A combination of considerations can be used for selecting a pattern. As noted herein, the pattern can be adaptable.

In step 1330, light reflected from the wafer is collected via a plurality of second optical fibers. The second optical fibers can be receive optical fibers and can be part of a fiber optic cable assembly connected to a spectrometer. For example, the plurality of second optical fibers can be optical fibers of fiber optic cable assembly 157.

The number of number of the plurality of second optical fibers can correspond to the number of individual optical inputs of the spectrometer but are not determined by the number of individual optical inputs. For example, the number of plurality of second optical fibers can be the same, more, or less than the number of individual optical inputs of the multiple input spectrometer.

The collected light is processed in step 1340. The collected light can be processed by a multiple input spectrometer for detection and conversion to digital signals. The collected light from each of the plurality of second optical fibers can be provided to a unique input of the multiple input spectrometer for the processing. For example, the light (or subbeams) on each one of the plurality of second optical fibers can be processed individually (or independently), in combination with at least one other one (a combination that is less than all), or can all be processed together.

The processing performed by the multiple input spectrometer can based on the combined information from individually processed subbeams, such as averaging output values. Various trends or different types of data could be extracted from processing the output values of the processed subbeams. Trend lines can be determined, for example, for each of the subbeams.

In step 1350, according to the processing one or more control trends for controlling the processing of the wafer in the processing chamber are provided to the processing chamber. The wafer can then be processed using the received control trends in step 1360. Method 1300 continues to step 1370 and ends.

The changes described above, and others, may be made in the optical measurement systems and subsystems described herein without departing from the scope hereof. For example, although certain examples are described in association with semiconductor wafer processing equipment, it may be understood that the optical measurement systems described herein may be adapted to other types of processing equipment such as roll-to-roll thin film processing, solar cell fabrication or any application where high precision optical measurement may be required. Furthermore, although certain embodiments discussed herein describe the use of a common light analyzing device, such as an imaging spectrograph, it should be understood that multiple light analyzing devices with known relative sensitivity may be utilized. Furthermore, although the term “wafer” has been used herein when describing aspects of the current invention, it should be understood that other types of workpieces such as quartz plates, phase shift masks, LED substrates and other non-semiconductor processing related substrates and workpieces including solid, gaseous and liquid workpieces may be used.

The embodiments described herein were selected and described in order to best explain the principles of the invention and the practical application, and to enable others of ordinary skill in the art to understand the invention for various embodiments with various modifications as are suited to the particular use contemplated. The particular embodiments described herein are in no way intended to limit the scope of the present invention as it may be practiced in a variety of variations and environments without departing from the scope and intent of the invention. Thus, the present invention is not intended to be limited to the embodiment shown, but is to be accorded the widest scope consistent with the principles and features described herein.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

As will be appreciated by one of skill in the art, portions disclosed herein may be embodied as a method, system, or computer program product. Accordingly, disclosed portions may take the form of an entirely hardware embodiment, an entirely software embodiment (including firmware, resident software, micro-code, etc.) or an embodiment combining software and hardware aspects all generally referred to herein as a “circuit” or “module.” Each of the example independent claims of the Summary can include one or more of the following elements in combination.

Element 1: wherein the optical system further includes a light pipe proximate to the source plane. Element 2: wherein the predetermined pattern of interrogation spots is adaptable. Element 3: wherein the plurality of first subbeams includes between two and ten subbeams. Element 4: wherein each of the plurality of second subbeams is collected and processed independently. Element 5: wherein the optical elements include at least one of a lens, a beam splitter, a beam stop, and an optical circulator. Element 6: wherein the pattern of the interrogation spots is one of a linear pattern, a circular pattern, a hexagonal pattern or a rectangular pattern. Element 7: wherein the light source provides the source light to the source plane fiberoptically and each of the plurality of first subbeams is defined by an individual optical fiber. Element 8: wherein the spectrometer is configured to receive the collected light from the image plane fiberoptically and each of the plurality of second subbeams is defined by an individual optical fiber. Element 9: wherein the individual optical fibers defining the plurality of first subbeams and the individual optical fibers defining the plurality of second subbeams are pairwise radially symmetric with respect to an axis of the optical system. Element 10: wherein the pairwise arrangement of the pluralities of first and second optical fibers is configured as a plurality of optical circulators.

Element 11: further including a light pipe proximate to the light source and plurality of first optical fibers. Element 12: wherein the plurality of interrogation spots includes between two and ten interrogation spots. Element 13: wherein the spectrometer individually processes the collected light from the plurality of second optical fibers. Element 14: wherein the pattern of the interrogation spots is one of a linear pattern, a circular pattern, a hexagonal pattern or a rectangular pattern. Element 15: further comprising defining a plurality of interrogation spots on the semiconductor wafer according to a predetermined pattern. Element 16: wherein the predetermined pattern is selected according to features to be monitored on the semiconductor wafer. Element 17: wherein the processing the collected light to provide one or more control trends for controlling the processing of the wafer includes combining collected light from a multiple of the plurality of second optical fibers.

What is claimed is:

1. An optical system, comprising:
a light source configured to provide source light to a source plane to form a plurality of first subbeams;
optical elements configured to modify each of the plurality of first subbeams to form a plurality of interrogation spots on a wafer according to a predetermined pattern, the optical elements further configured to modify each of the plurality of first subbeams upon reflection from the wafer to form a plurality of second subbeams upon an image plane; and
a spectrometer configured to receive collected light from the plurality of second subbeams.

2. The optical system as recited in claim 1, wherein the optical system further includes a light pipe proximate to the source plane.

3. The optical system as recited in claim 2, wherein the predetermined pattern of interrogation spots is adaptable.

4. The optical system as recited in claim 1, wherein the plurality of first subbeams includes between two and ten subbeams.

5. The optical system as recited in claim 1, wherein each of the plurality of second subbeams is collected and processed independently.

6. The optical system as recited in claim 1, wherein the optical elements include at least one of a lens, a beamsplitter, a beam stop, and an optical circulator.

7. The optical system as recited in claim 1, wherein the pattern of the interrogation spots is one of a linear pattern, a circular pattern, a hexagonal pattern or a rectangular pattern.

8. The optical system as recited in claim 1, wherein the light source provides the source light to the source plane fiberoptically and each of the plurality of first subbeams is defined by an individual optical fiber.

9. The optical system as recited in claim 8, wherein the spectrometer is configured to receive the collected light from the image plane fiberoptically and each of the plurality of second subbeams is defined by an individual optical fiber.

10. The optical system as recited in claim 9, wherein the individual optical fibers defining the plurality of first subbeams and the individual optical fibers defining the plurality of second subbeams are pairwise radially symmetric with respect to an axis of the optical system.

11. A semiconductor processing system, comprising:
a processing chamber;
a light source configured to provide source light to a plurality of first optical fibers,
a spectrometer configured to receive collected light from a plurality of second optical fibers; and
an interrogation region including a plurality of interrogation spots on a wafer within the processing chamber, wherein each of the plurality of interrogation spots is defined by a pairwise arrangement of the pluralities of first and second optical fibers.

12. The semiconductor processing system as recited in claim 11, wherein the pairwise arrangement of the pluralities of first and second optical fibers is configured as a plurality of optical circulators.

13. The semiconductor processing system as recited in claim 11, further including a light pipe proximate to the light source and plurality of first optical fibers.

14. The semiconductor processing system as recited in claim 11, wherein the plurality of interrogation spots includes between two and ten interrogation spots.

15. The semiconductor processing system as recited in claim 11, wherein the spectrometer individually processes the collected light from the plurality of second optical fibers.

16. The semiconductor processing system as recited in claim 11, wherein the pattern of the interrogation spots is one of a linear pattern, a circular pattern, a hexagonal pattern or a rectangular pattern.

17. A method for processing a semiconductor wafer, comprising:
illuminating a wafer within a semiconductor processing chamber via a plurality of first optical fibers with light provided by a light source;
collecting the light reflected from the wafer via a plurality of second optical fibers;
processing the collected light using a multiple input spectrometer; and
providing one or more control trends for controlling the processing of the wafer according to the processing.

18. The method for processing a semiconductor wafer as recited in claim 17, further comprising defining a plurality of interrogation spots on the semiconductor wafer according to a predetermined pattern.

19. The method for processing a semiconductor wafer as recited in claim 18, wherein the predetermined pattern is selected according to features to be monitored on the semiconductor wafer.

20. The method for processing a semiconductor wafer as recited in claim 17, wherein the processing the collected light to provide one or more control trends for controlling the processing of the wafer includes combining collected light from a multiple of the plurality of second optical fibers.
